(19) United States
(12) Patent Application Publication
(10) Pub. No.: US 2002/0164881 A1
(43) Pub. Date: Nov. 7, 2002

(54) Method for manufacturing semiconductor device

(75) Inventor: Hidetaka Nambu, Tokyo (JP)

Correspondence Address: Patent Group, Hutchins, Wheeler & Dimmar, 101 Federal Street, Boston, MA, 02110, US

(73) Assignee: NEC Corporation

(21) Appl. No.: 10/087,498

(22) Filed: Mar. 1, 2002

(30) Foreign Application Priority Data
Mar. 1, 2001 (JP) 2001-057407

(51) Int. Cl. H01L 21/302

(52) U.S. Cl. 438/714

(57) ABSTRACT

A hard mask is formed on an organic interlayer film and a resist pattern is formed on the hard mask. A first pattern of the hard mask is formed by etching the hard mask using said resist pattern as a mask and a second pattern of the organic interlayer film is formed by etching said organic interlayer film using said first pattern as a mask. Said organic interlayer film is etched using a gas for the etching and is etched (a first etching) by applying a first pressure on the gas and then etched (a second etching) by applying a second pressure on the gas. The second pressure is lower than the first pressure. The gas includes N₂ gas. In this case, the first etching is performed by etching gas of a first concentration on the N₂ gas, and then the second etching is performed by etching gas of a second concentration on the N₂ gas. The second concentration is lower than the first concentration. By changing the gas pressure and the N₂ concentration, the grooves having excellent perpendicularity can be formed in the organic interlayer film.

### BACKGROUND OF THE INVENTION

1. Field of the Invention

The present invention relates to a method for manufacturing a semiconductor device. Particularly, the present invention relates to a method for manufacturing a semiconductor device, in which an organic film is etched with a design rule of 0.25 μM or less etching-width.

2. Description of Related Art

In connection with miniaturizing an electronic circuit, it has been desired to solve a problem of RC delay. For solving the RC delay problem, it has been recommended to use an organic interlayer film with a low dielectric constant as an interlayer insulation film. In case of using such an organic interlayer film, Japanese Patent Laid-Open Publication No. 2000-21635 discloses how to perform an appropriate etching on the organic interlayer film. Since there is disclosed an etching gas to be appropriately used when the organic interlayer film is subjected to an anisotropic etching, the document is noticeable. In this document, however, any disclosure concerned about a perpendicular micro-etching to be required in connection with miniaturizing the electronic circuit.

In case of an etching on an organic low-K film with a design rule of 0.25 μm or less etching-width, an one-step etching using a gas such as N₂/H₂, NH₃/N₂, or NH₃ has been typically performed. In case of a design rule of 0.25 μm or less etching-width, it is difficult to keep the perpendicularity to be satisfied by the one-step etching because the shape of the film after the etching becomes one having a remarkably bowed or sloped edge.

For micro-sizing the etching on the organic insulation film, there is a need to establish the technology for performing a perpendicular etching without causing a bowed or sloped edge of the film. Furthermore, it is also required to perform the perpendicular etching so as to flexibly fit to a wide or narrow etching width.

### SUMMARY OF THE INVENTION

An object of the present invention is to provide a method for manufacturing a semiconductor device capable of establishing a technology to perform a perpendicular etching for micro-sizing the etching on an organic insulation film.

Another object of the present invention is to provide a method for manufacturing a semiconductor device capable of performing a perpendicular etching by flexibly dealing with a wide or narrow etching width.

Means for solving the problems can be expressed as follows. Technical matters in the following expressions will be written with distinguishing numbers, symbols, or the like in the parentheses. These numbers, symbols, or the like are coincident with reference numbers and reference symbols attached to the technical matters that make up two or more embodiments or make up at least one embodiment or two or more examples of the present invention, especially those attached to the technical matters expressed in the figures corresponding to such embodiments or examples. These reference numbers and reference symbols define the correspondence or bridge between the technical matters described in the claims and technical matters described in the embodiments or the examples. Such correspondence or bridges do not mean that the technical matters in the claims can be interpreted so as to be confined within those of the embodiments or examples.

A method for manufacturing a semiconductor device of the present invention includes the steps of; forming a hard mask (3) on an organic interlayer film (4); forming a resist layer (1) having a resist pattern (6, 7) on the hard mask (3); forming a first pattern (8,9) of the hard mask (3) by etching the hard mask (3) using the patterns (6, 7) as a mask; and forming a second pattern (11, 12) of the organic interlayer film (4) by etching the organic interlayer film (4) using the first pattern (8, 9) as a mask. The step of etching the organic interlayer film (4) includes the steps of: using gas for etching, performing a first etching by applying a first pressure on the gas; and then, performing a second etching by applying a second pressure on the gas, where the second pressure is lower than the first pressure. Therefore, the organic interlayer film can be etched with two or more etching steps while increasing the pressure of gas, so that a groove having first and second patterns to be formed on the organic interlayer film will keep its perpendicularity.

Preferably, a third pressure may be applied on the gas to perform a third etching. Furthermore, the degree of freedom in designing the width of groove can be increased by increasing the number of etching steps over time and also by continuously changing the composition of gas over time.

The gas may include N₂ gas. In this case, the method further includes the additional steps of providing N₂ gas with a first concentration to perform the first etching, and providing N₂ gas with a second concentration to perform the second etching. The second concentration is lower than the first concentration. Furthermore, the degree of freedom in designing the width of the groove can be increased by increasing the number of etching steps over time and also by continuously changing the composition of gas over time.

Preferably, the gas may further include H₂ gas. Preferably, the gas may further include NH₃ gas. For the gas, it is possible to use NH₃ gas alone. A raw material of the hard mask (3) may be preferably selected from inorganic materials with low dielectric constants, such as SiO₂, SiN, SiC, SiCN, MSQ, and HSQ. The dielectric constant can be further decreased in some of films prepared from these inorganic materials because of the induction of vacancy in the film.

The second pattern is composed of two or more grooves (11, 12) with different widths from each other. In this case, the width of each groove may be 0.25 μm or less. Alternatively, the grooves may have a groove of 0.25 μm or less in its width and that of 0.25 μm to 10 μm in its width. Each of these grooves has an excellent perpendicularity.

### BRIEF DESCRIPTION OF THE DRAWINGS

FIG. 1 is a sectional view illustrating a step of one embodiment according to a method for manufacturing a semiconductor device of the present invention;

FIG. 2 is a sectional view illustrating a step after the step shown in FIG. 1;

FIG. 3 is a sectional view illustrating a step after the step shown in FIG. 2;

FIG. 4 is a sectional view illustrating a step after the step shown in FIG. 3; and

FIG. 5 is a sectional view illustrating a step after the step shown in FIG. 4.

### DETAILED DESCRIPTION OF THE PREFERRED EMBODIMENTS

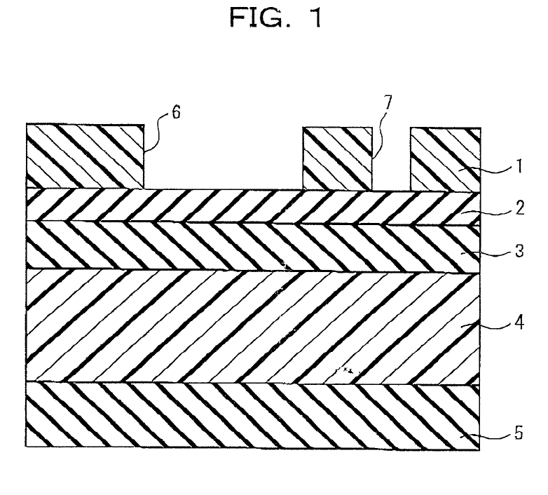

A method for manufacturing a semiconductor device as a preferred embodiment of the present invention will be described with reference to the attached drawings as shown in FIG. 1, a resist layer 1 is formed on a hard mask 3 through an anti-reflective coating (ARC) film 2. The hard mask 3 is preferably prepared as a film made of one selected from the group consisting of SiO₂, SiN, SiC, SiCN, MSQ, and HSQ. It is preferable to induce vacancy in the film made of such a material. The vacancy allows a further decrease in the dielectric constant of the film 3. In addition, an organic interlayer film 4 is prepared as an organic low-K film and is formed on the lower side of the hard mask 3 so as to be provided as the etching-target layer. Furthermore, a silicon oxide layer 5 is formed as a substrate layer on the lower surface of the organic interlayer film 4.

The semiconductor device is manufactured by the following steps S1 to S5 which are sequentially performed.

Step S1:

The etching-target substrate, as shown in FIG. 1, described above is prepared. The resist layer 1 has a first groove portion 6 with a large width defined as a first etching width and a second groove portion 7 with a small width defined as a second etching width.

Step S2:

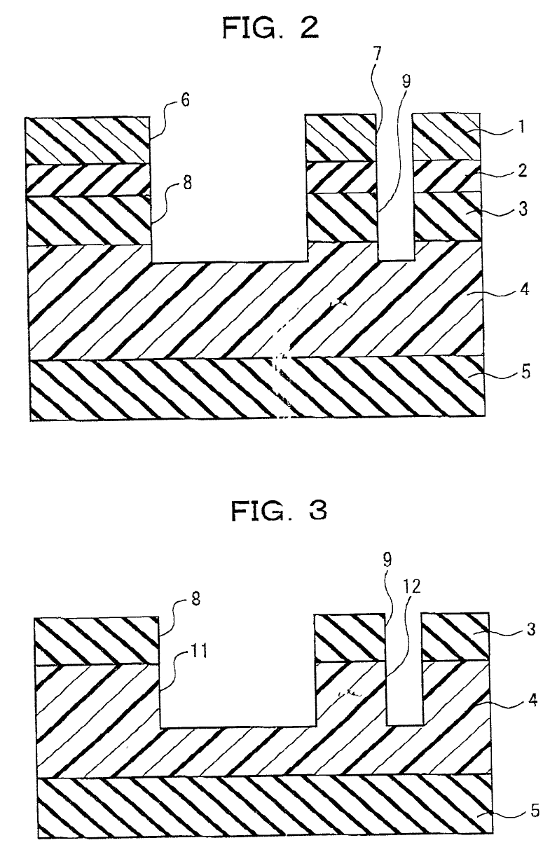

As shown in FIG. 2, both the resist layer 1 and the ARC film 2 are etched with the action of a mixture gas of CF₄/Ar/O₂ provided from the upper side of the resist layer 1 prepared as a patterning layer for the etching-target substrate formed in the step S1 described above. Subsequently, the mixture gas further acts on the hard mask 3, so that the hard mask 3 can be etched with the mixture gas. As a result, in the step S2, a first through groove portion 8 and a second through groove portion 9 passing through the ARC film 2 and the hard mask 3 are formed. These portions 8, 9 extend continuously from the first groove portion 6 and the second groove portion 7 respectively in the direction substantially perpendicular to the surface of the substrate 5.

STEPS S3 TO S5:

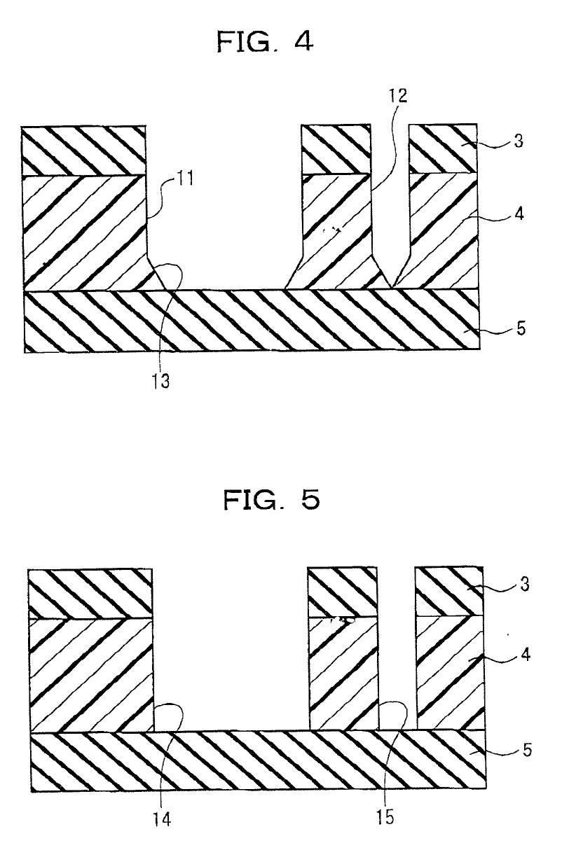

The etching gas is changed from the mixture gas of F₄/Ar/O₂ to another mixture gas of N₂/H₂. The step S3 shown in FIG. 3, the step S4 shown in FIG. 4, and the step S5 shown in FIG. 6 are sequentially performed under their different etching conditions as shown in the following Table 1, respectively.

TABLE 1

| Step | Pressure (mTorr) | N₂ concentration (%) |
|---|---|---|
| S3 | 400-600 | 40-75 |
| S4 | 100-400 | 25-40 |
| S5 | 5-100 | 7-25 |

The step S3 continues until the resist layer 1 and the hard mask 2 are removed completely At the time of completing the removal, a first organic-film groove portion 11 and a second organic-film groove portion 12 have reached at a depth of almost one-half of the organic interlayer film 4 respectively in the direction along the thickness of the organic interlayer film 4. As shown in the figure, the first organic-film groove portion 11 and the second organic-film groove portion 12 are formed in the organic interlayer film 4 such that they extend continuously from the first through groove portion 8 and the second through groove portion 9, respectively.

In the step S4, the fist organic-film groove portion 11 and the second organic-film groove portion 12 reach the top of the silicon oxide layer 5 as the organic interlayer film 3 is etched completely in the direction along the thickness thereof. In the step S4, as shown in FIG. 4, the lower portion of each of the first organic-film groove portion 11 and the second organic-film groove portion 12 becomes narrow. In the step S5, the pressure and the N₂ concentration are more decreased so as to allow an etching with an excellent perpendicularity and a low spattering efficiency

In the step S3 at a high pressure of 400 mTorr or more, a micro-loading effect decreases as a sub-trench in a large pattern decreases in the high-pressure region to allow an etching at substantially the same etching rate for a pattern of 0.1 μm to 1 μm or more. Therefore, a good perpendicularity can be obtained In the step S3, furthermore, the resist film 1 and the ARC film 2 remain on the upper side of the hard mask 3, so that the hard mask 3 can be prevented from causing the sloped edge thereof in spite of the presence of a large amount of N₂ gas (40 to 75%) having a high spattering efficiency. In this respect, a good perpendicularity can be also ensured. In the region with a N₂ concentration of 40 to 75%, the etching rate of the organic low-K film 4 (i.e., the organic film) becomes maximum, so that the advantage of shortening the processing time can be obtained.

In the step S4 at a decreased pressure of 100 to 400 mTorr and a decreased N₂ concentration of 25 to 40%, the etching continues to the end of the organic interlayer film 4. During the period of such an etching, the decrease in pressure keeps a good etching shape with respect to the perpendicularity without causing bowing. In the step S4, furthermore, the resist layer 1 is removed and the hard mask 3 is significantly sputtered In this case, however, the concentration of N₂ decreases to about 25 to 45%. Therefore, the perpendicularity (perpendicular shape) can be kept well without causing the sloped edge of the mask 3 because of the decrease in the sputtering efficiency. In the step S5 at a decreased N₂ concentration of 7 to 25% under extremely low pressure, it is possible to proceed the processing with the suppression of sputtering on the hard mask 3 while keeping the perpendicularity (perpendicular processing) well.

Consequently, Such changes in N₂ concentration allow the perpendicular processing of the organic low-K film 4 using only N₂/H₂ gas. In this case, the hard mask 3 with a micro-pattern of 0.2 μm or less or with a large pattern of 10 μm or more can be used, causing only a small sloped edge of the mask 3. Regarding the changes in N₂ concentration, but not limited to, there are three steps with different N₂ concentrations in the above embodiment. Depending on the target of the processing, good results can be obtained by two steps with different N₂ concentrations or by four or more steps with different N₂ concentrations.

Instead of N₂/H₂ mixture gas/ NH₃/N₂ mixture gas may be preferably used. Furthermore, instead of N₃/H₂ mixture gas, NH₃ may be preferably used alone. In this case, the concentration of N₂ cannot be changed, so that two or more steps only with different NH₃ concentration my provide a good perpendicular processability can be attained.

As a raw material of the hard mask 3, an inorganic low dielectric constant film such as SiO₂, SiN, SiC, SiCN, MSQ, or HSQ may be preferably used. In each of these inorganic films with their respective low dielectric constants, vacancy may be induced. If there is the induction of vacancy, the dielectric constant of such a film can be decreased more. Therefore, such a material is substantially effective to proceed an etching with the non-significant sloped edge of the hard mask 3. Furthermore, the present invention can be applied on an organic film with a Si concentration of about 3%, so that an etching can be performed to provide an etching shape with the non-significant sloped edge of the hard mask 3 and the non-significant residual of etching.

Consequently, the method for manufacturing a semiconductor device of the present invention is allowed to provide a good perpendicular processability of the organic interlayer film.

What is claimed is:

1. A method for manufacturing a semiconductor device, comprising the steps of:
forming a hard mask on an organic interlayer film;
forming a resist pattern on the hard mask;
etching said hard mask using said resist pattern as a mask to form a first pattern of the hard mask; and
etching said organic interlayer film using said first pattern of the hard mask as a mask to form a second pattern of the organic interlayer film, the step of etching said organic interlayer film using a gas for the etching and including the steps of; performing a first etching of said organic interlayer film by applying a first pressure on the gas; and thereafter performing a second etching of said organic interlayer film by applying a second pressure on the gas, which is lower than the first pressure.

2. The method for manufacturing a semiconductor device according to claim 1, further comprising the step of:
performing a third etching by applying a third pressure on the gas, after said second etching, the third pressure being lower than the second pressure.

3. The method for manufacturing a semiconductor device according to claim 1, wherein
said gas includes N₂ gas.
said first etching is done by a etching gas which has a first concentration of said N₂ gas, and
said second etching is done by a etching gas which has a second concentration of said N₂ gas, the second concentration being lower than said first concentration.

4. The method for manufacturing a semiconductor device according to claim 2, wherein
said gas includes N₂ gas,
said first etching is done by a etching gas which has a first concentration of said N₂ gas, and
said second etching is done by a etching gas which has a second concentration of said N₂ gas, the second concentration being lower than said first concentration.

5. The method for manufacturing a semiconductor device according to claim 2, wherein
said gas includes N₂ gas,
said first etching is done by a etching gas which has a first concentration of said N₂ gas,
said second etching is done by a etching gas which has a second concentration of said N₂ gas, the second concentration being lower than said first concentration, and
said third etching is done by a etching gas which has a third concentration of said N₂ gas, the third concentration being lower than said second concentration.

6. The method for manufacturing a semiconductor device according to claim 3, wherein
said gas further includes H₂ gas.

7. The method for manufacturing a semiconductor device according to claim 4, wherein
said gas further includes H₂ gas.

8. The method for manufacturing a semiconductor device according to claim 5, wherein
said gas further includes H₂ gas.

9. The method for manufacturing a semiconductor device according to claim 3, wherein
said gas further includes NH₃ gas.

10. The method for manufacturing a semiconductor device according to claim 4, wherein
said gas further includes NH₃ gas

11. The method for manufacturing a semiconductor device according to claim 5, wherein
said gas further includes NH₃ gas.

12. The method for manufacturing a semiconductor device according to claim 1, wherein
said gas consists of NH₃ gas.

13. The method for manufacturing a semiconductor device according to claim 1, wherein
said second pattern has a plurality of grooves with widths different from each other.

14. The method for manufacturing a semiconductor device according to claim 2, wherein
said second pattern has a plurality of groove with widths different from each other.

15. The method for manufacturing a semiconductor device according to claim 3, wherein
said second pattern has a plurality of grooves with widths different from each other.

16. The method for manufacturing a semiconductor device according to claim 13, wherein
said grooves have the width of 0.25 μm or less.

17. The method for manufacturing a semiconductor device according to claim 14, wherein
said grooves have the width of 0.25 μm or less.

18. The method for manufacturing a semiconductor device according to claim 15, wherein
said grooves have the width of 0.25 μm or less.

19. The method for manufacturing a semiconductor device according to claim 13, wherein
a part of said grooves have the width of 0.25 μm or less and the remaining groove have the width of 0.25 μm to 10 μm.

20. The method for manufacturing a semiconductor device according to claim 14, wherein
a part of said grooves have the width of 0.25 μm or less and the remaining grooves have the width of 0.25 μm to 10 μm.

21. The method for manufacturing a semiconductor device according to claim 15, wherein
a part of said grooves have the width of 0.25 μm or less and the remaining grooves have the width of 0.25 μm to 10 μm.

22. The method for manufacturing a semiconductor device according to claim 1, wherein
said hard mask comprises two layers.

23. The method for manufacturing a semiconductor device according to claim 1, wherein
said hard mask is formed of an inorganic material with a low dielectric constant selected from the group consisting of SiO₂, SiN, SiC, SiCN, MSQ, and HSQ.

24. The method for manufacturing a semiconductor device according to claim 23, wherein
said inorganic material of said hard mask has vacancies.
